(19) United States
(12) Patent Application Publication
(10) Pub. No.: US 2005/0136643 A1
(43) Pub. Date: Jun. 23, 2005

(54) Dielectric film forming method for semiconductor device and semiconductor device

(75) Inventor: Junichi Takeuchi, Chino-city (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/982,797

(22) Filed: Nov. 8, 2004

(30) Foreign Application Priority Data
Nov. 11, 2003 (JP) 2003-381278

(51) Int. Cl. H01L 21/4763; H01L 23/48; H01L 23/52; H01L 29/40

(52) U.S. Cl. 438/622; 257/752

(57) ABSTRACT

Aspects of the invention can provide semiconductor devices and dielectric film forming methods for semiconductor devices in which inter-wiring dielectric films can be formed only in fine gaps among wirings, and which does not have influences by absorption and discharge of gas and moisture from dielectric films and can be manufactured while suppressing the use of the material, electrical power and PFC. Before forming inter-wiring dielectric films (SOG films) formed through coating liquid material, water repelling films can be formed on surfaces of wirings and a substrate, and later a slit coat method that uses the capillary phenomenon can be performed. As a result, the liquid material can be selectively filled only in fine gaps between wirings. Also, SOG films are not formed on upper surfaces of the wirings where holes are formed, or on surfaces of a substrate, such that the SOG films are not exposed on inner walls of the holes.

### BACKGROUND OF THE INVENTION

1. Field of Invention

Aspects of the invention relate to a dielectric film forming method for a semiconductor device that can include an inter-wiring dielectric film and an interlayer dielectric film for planarizing irregularities caused by wirings formed on a substrate.

2. Description of Related Art

A variety of related art methods have been used with miniaturization of inter-wirings, for forming inter-wiring dielectric films that fill gaps between wirings to planarize irregularities caused by the wirings formed on a substrate and interlayer dielectric films in multiple layered wirings. For example, there is a related art method in which an inter-wiring dielectric film is formed from a SOG (spin on glass) film through coating liquid material that is readily filled in fine gaps between wirings, and them an interlayer dielectric film is formed on the SOG film by plasma CVD. Also, a method to form inter-wiring dielectric films by plasma CVD is known. According to this method, sputtering is conducted to prevent abnormal growth from corners or the like of wirings, and portions that grow excessively are selectively removed to form inter-wiring dielectric films (High Density Plasma CVD (hereafter called DPCVD)). Then, an interlayer dielectric film is formed on the inter-wiring dielectric films by an ordinary plasma CVD.

As a method to prevent inter-wiring dielectric films from being formed on upper surfaces of wirings, the following related art method can be used. Photoresist that is located only on conductive layers (wirings) is formed, dielectric material is coated only between the conductive layers, the photoresist is removed, and then the dielectric material is sintered to form inter-wiring dielectric films. Thereafter, according to the related art method, an upper dielectric film (interlayer dielectric film) that covers the conductive layers and the inter-wiring dielectric films is formed. See, for example, Japanese Laid-open Patent Application HEI 5-291249 (page 2). Also, according to another method disclosed, after an inter-wiring dielectric film is formed to cover upper surfaces of wirings, the entire surface can be etched to the upper surfaces of the wirings. Then, an interlayer dielectric film is formed over the entire surface with a O3-TEOS oxide film for planarizing the surface. See, for example, Japanese Laid-open Patent Application HEI 10-92934 (page 3).

### SUMMARY OF THE INVENTION

When an SOG film is used as an inter-wiring dielectric film, liquid material can be coated by spin coating not only between miniaturized wirings, but also over the entire surface of the substrate. Referring to FIG. 18, the structure of a dielectric film 6 obtained when liquid material is coated by spin coating is described below.

In the application by spin coating, the SOG film that is the inter-wiring dielectric film is formed on upper surfaces of wirings 2 and surfaces of the substrate 1. In a process to be conducted later, an interlayer dielectric film 5 can be formed by plasma CVD, and the entire dielectric film 6 is planarized by CMP or the like. Then, holes 8 are formed in the dielectric film 6 for making contact between the wirings 2 and the substrate 1 and upper wirings (not shown). In this case, the SOG films that are present as the inter-wiring dielectric films 4 on the upper surfaces of the wirings 2 and the surface of the substrate 1 are exposed at lower inner walls of the holes 8.

The SOG film, as the inter-wiring dielectric film used in the spin coating, can be an organic material, and even after it is sintered, gas and moisture are absorbed and discharged. Due to the gas and moisture discharge phenomenon, changes in the shape and constrictions are caused in the holes when they are formed. Also, there is a problem in that peeling of conductive sections 3 formed in the holes 8 may occur, such that electrical connection between lower wirings and upper wirings through the conductive sections 3 becomes difficult, and the reliability of the wirings lowers. Also, the spin coating requires a large amount of liquid material for forming SOG films, and therefore there is a problem of a low use efficiency of the material. It is noted that the use efficiency of the material is about 5%.

In the method in which an inter-wiring dielectric film is formed by HDPCVD, and then an interlayer dielectric film is formed, the inter-wiring dielectric film is also formed by HDPCVD that is one type of plasma CVD. Although the problem by absorption and discharge of gas and moisture is few with the plasma CVD film, a uniform film growth is difficult at a minute level due to the problem of variations in the film growth due to differences in the flow of gas used and locations of the CVD film. Therefore, by using a large amount of PFC (perfluorocarbon) gas while conducting selective sputtering of dielectric films, the dielectric films are formed. Therefore, there are problems of a large amount of power consumption by the CVD apparatus that needs the vacuum and the use of PFC gas that affects the environment.

To prevent SOG films as inter-wiring dielectric films from being formed on upper surfaces of wirings, there is a method in which photoresist is formed on the upper surfaces of the wirings, and a method in which the SOG films are etched back to the upper surfaces of the wirings. According to these related art methods, since SOG films do not exist on the upper surfaces of the wirings, the problems by discharge and absorption of gas and moisture of SOG films are few. However, when making contacts with the substrate itself, the problems by discharge and absorption of gas and moisture of SOG films are not resolved because the SOG films are formed on the substrate. Moreover, the addition of the etch back process is necessary, and the problems concerning the material, the electric power, and PFC exist.

An aspect of the invention can provide semiconductor devices and dielectric film forming methods for semiconductor devices in which inter-wiring dielectric films can be formed only in fine gaps among wirings, and which does not have influences by absorption and discharge of gas and moisture from dielectric films and can be manufactured while suppressing the use of the material, electrical power and PFC.

Aspects of the invention pertain to a dielectric film forming method for a semiconductor device for forming a dielectric film including an inter-wiring dielectric film and an interlayer dielectric film for planarizing irregularities caused by wirings formed on a substrate. The method can include a step of forming wirings on a substrate, a step of forming a liquid repelling film on surfaces of the wirings and surfaces of the substrate, a step of forming an inter-wiring dielectric film through coating liquid material on a surface where the liquid repelling film is formed, a step of forming an interlayer dielectric film on the wirings and the inter-wiring dielectric film, and a step of polishing and planarizing an upper surface of the interlayer dielectric film.

According to this method, after the liquid repelling film is formed on the upper surfaces of the wirings and the surfaces of the substrate, the inter-wiring dielectric films are formed through coating the liquid material. As a result, the interlayer dielectric film can be prevented from being formed on the surfaces of the wirings and the surfaces of the substrate because the liquid material is repelled on the upper surfaces of the wirings and the surfaces of the substrate.

Also, the present invention can include that the liquid material is coated by a slit coat method in which, while contacting liquid material exuded from an end face of a slit with a surface of the substrate where the wirings are provided, the slit is scanned.

According to this method, the liquid material can be selectively filled in between the wirings by the capillary phenomenon caused by the fine gaps among the wirings, and inter-wiring dielectric films can be prevented from being formed in wide areas among the wirings where an interlayer dielectric film can be formed by plasma CVD. Also, because only fine gaps among the wirings are filled by using the liquid material that exudes from the slit end face, the amount of the liquid material used can be small.

Furthermore, the invention can further include a step of removing a part of the liquid repelling film between the step of forming the liquid repelling film and the step of forming the inter-wiring dielectric film. According to this exemplary method, the liquid repelling films other than portions where the liquid repelling films are required, such as the upper surfaces of the wirings and the surface of the substrate are removed, such that the semiconductor device can reduce influences by contamination from the liquid repelling films and changes in the electrical property.

Moreover, the invention can include a step of removing all or a part of exposed portions of the liquid repelling film between the step of forming the inter-wiring dielectric film and the step of interlayer dielectric film. According to this exemplary method, the liquid repelling films that become unnecessary after forming the inter-wiring dielectric films can be removed, and the adhesion between the interlayer dielectric films and the wirings and the substrate improves. Also, the semiconductor device can reduce influences by contamination from the liquid repelling films and changes in the electrical property. Further, the invention can include that the inter-wiring dielectric film is an SOG film.

According to this method, since SOG film material is used as a liquid material with viscosity and flowability that are suitable for the filling of minute gaps between the wirings, the capillary phenomenon caused by the fine gaps between the wirings can be effectively used. Moreover, the invention is characterized in that the step of forming the interlayer dielectric film includes a plasma CVD step.

According to this exemplary method, because plasma CVD films with few absorption and discharge of gas and moisture are formed on the upper surfaces of the wirings and in wide substrate regions among the wirings where holes are formed, changes and constrictions in the shape of holes due to the gas and moisture discharge phenomenon, and peelings of conductive sections thereafter formed within the holes are difficult to occur. Moreover, the electrical connection between lower wirings and upper wirings through conductive sections within the holes can become more secured, and the reliability of the wirings would not decrease.

Further, the invention can include that the step of polishing and planarizing the upper surface of the interlayer dielectric film is CMP. According to this exemplary method, the multilayer wirings are planarized in a wide range, and can be accurately formed even when the wirings in the upper layer are miniaturized.

Aspects of the invention can pertain to a semiconductor device having a dielectric film including an inter-wiring dielectric film and an interlayer dielectric film for planarizing irregularities caused by wirings formed on a substrate. The invention can include an inter-wiring dielectric film formed by filling between the wirings to a predetermined height below an upper surface of the wirings, a dielectric film including an interlayer dielectric film formed on the wirings and the inter-wiring dielectric film, and a liquid repelling film formed on at least one of a boundary between the wirings and the inter-wiring dielectric film and a boundary between the substrate and the interlayer dielectric film.

According to this structure, the height of the inter-wiring dielectric film filled between the wirings can be lower than the upper surface of the wirings. Therefore, when electrical connections are made through conductive sections within holes from upper surfaces of the wirings to wirings in an upper layer, the inter-wiring dielectric films are not exposed at inner walls of the holes. Accordingly, influences of absorption and discharge of gas and moisture from the inter-wiring dielectric films to the hole sections can be reduced.

Also, the invention can include that the inter-wiring dielectric film is formed between the wirings with a pitch narrower than a pitch of wirings where holes are formed. According to this exemplary structure, the inter-wiring dielectric films are not formed in portions where holes to make electrical connections between upper surfaces of the wirings and surfaces of the substrate are formed, such that influences of absorption and discharge of gas and moisture from the inter-wiring dielectric films to the hole sections can be reduced.

Furthermore, the invention is characterized in that the inter-wiring dielectric film is formed through coating a liquid material. According to this exemplary structure, because the inter-wiring dielectric films are formed through coating a liquid material, films are formed in fine gaps between the wirings, and can play the role as dielectric films.

Moreover, aspects of the invention can include that the interlayer dielectric film is a plasma CVD film. According to this exemplary structure, the inner walls of the holes are composed of plasma CVD films that have excellent characteristics and mechanical strength as dielectric films, such that the reliability of wiring through the conductive sections within the holes improves.

The invention can also pertain to a semiconductor device having a dielectric film including an inter-wiring dielectric film and an interlayer dielectric film for planarizing irregularities caused by wirings formed on a substrate. The device can include a dielectric film formed by any of the dielectric film forming methods described above. According to this structure, the process of forming inter-wiring dielectric films in fine gaps between the wirings is simple and easy, and a semiconductor device that can be manufactured with the quality thereof unaffected can be obtained, while suppressing the use of the material, electrical power and PFC (perfluorocarbon).

### BRIEF DESCRIPTION OF THE DRAWINGS

This invention will be described with reference to the accompanying drawings, wherein like numerals reference like elements, and wherein:

FIG. 1 shows a cross-sectional view schematically showing a semiconductor device;

FIG. 2 shows a cross-sectional view for describing the step of forming wirings;

FIG. 3 shows a cross-sectional view for describing the step of forming water repelling films;

FIG. 4 shows a cross-sectional view for describing the step of forming water inter-wiring dielectric films;

FIG. 5 shows a cross-sectional view for describing the step of forming water interlayer dielectric films;

FIG. 6 shows a cross-sectional view for describing the polishing (CMP) and planarizing step;

FIG. 7 shows a cross-sectional view for describing the step of forming holes;

FIG. 8 shows a cross-sectional view after conductive sections are formed;

FIG. 9 shows a cross-sectional view for describing coating by a slit;

FIG. 10 shows a cross-sectional view for describing the step of forming wirings;

FIG. 11 shows a cross-sectional view for describing the step of forming water repelling films;

FIG. 12 shows a cross-sectional view for describing the step of partially removing water repelling films;

FIG. 13 shows a cross-sectional view for describing the step of forming inter-wiring dielectric films;

FIG. 14 shows a cross-sectional view for describing the step of removing water repelling films;

FIG. 15 shows a cross-sectional view for describing the step of forming interlayer dielectric films;

FIG. 16 shows a cross-sectional view for describing the polishing (CMP) and planarizing step;

FIG. 17 shows a cross-sectional view for describing the step of forming holes; and

FIG. 18 shows a cross-sectional view when inter-wiring dielectric films are formed by spin coat.

### DETAILED DESCRIPTION OF PREFERRED EMBODIMENTS

It has been discovered that when a liquid material for forming inter-wiring dielectric films, which is exuded from an end face of a slit, is coated by scanning the slit while contacting the liquid material with surfaces of a substrate on a wiring side after a water repelling film is formed on surfaces of wirings and surfaces of the substrate, the liquid material can be selectively filled between wirings having an inter-wiring distance smaller than the width of the slit.

Exemplary embodiments of the invention are described below with reference to the accompanying drawings. It should be understood that the invention is not limited to exemplary embodiments described below. Skilled person in the art can add various changes to the following exemplary embodiments, thereby carrying out the invention to its maximum, and such changes are contained in the range of patent claims.

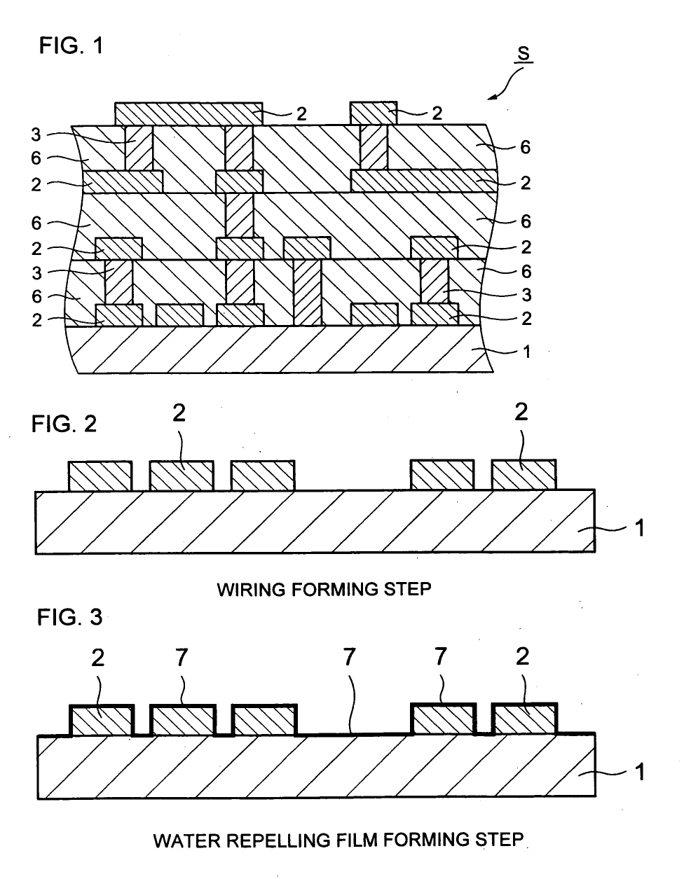

FIG. 1 is a cross-sectional view of a portion including wirings 2, conductive sections 3 within holes and dielectric films 6 of a semiconductor device S. The substrate 1 may be a Si wafer, or a glass substrate. Also, the substrate 1 in the invention may include a dielectric film 6 provided on a Si wafer or a glass substrate. For example, when two or more layers of dielectric films 6 are provided, wirings 2 are formed on a dielectric film 6 in the second layer or above, and in this case, a substrate is deemed to include the dielectric film 6 in a lower layer below the wirings 2 formed. When two or more layers of dielectric films 6 are provided, a semiconductor device S having a dielectric film 6 that is formed by a dielectric film forming method of the invention in any of the layers including the dielectric films 6 shown in FIG. 1 can be obtained.

FIG. 2-FIG. 8 are cross-sectional views of an exemplary semiconductor device illustrated for describing a dielectric film forming method for a semiconductor device in accordance with an embodiment of the present invention. The embodiment is described according to each of the steps.

FIG. 2 shows a cross-sectional view for describing the step of forming wirings. Wirings 2 may use metal (for example, Al or Cu with Si added therein) or oxide electroconductive films (for example, ITO). The pattern of the wirings 2 can be obtained by any well known photolithography and etching steps (washing, film growth, washing, coating of photosensitive material, exposure, development, etching, and peeling of photosensitive material). There are narrow and wide pitches among the wirings 2 depending on their locations, and the narrow pitch is deemed to be 0.3 μm.

FIG. 3 shows a cross-sectional view of a semiconductor device for describing the step of forming a water repelling film. A water repelling film 7 is formed with a fluororesin plasma polymerized film. More specifically, a substrate can be placed in a processing chamber (not shown), which is then placed in a predetermined reduced pressure state, and liquid organic substance composed of linear PFC or the like (for example, C4F10 or C8F18) is heated to evaporate, and introduced into the processing chamber with carrier gas (for example, nitrogen or argon). At this time, CF4 gas can also be introduced at the same time. In addition, the source gases in the processing chamber are activated by introducing high-frequency power into the processing chamber and generating plasma. As a result, bonds of the linear organic substance are partially cut and become active, the active linear organic substance arrived at the surface of the substrate polymerize, and a fluororesin plasma polymerized film is formed on the entire surface of the substrate.

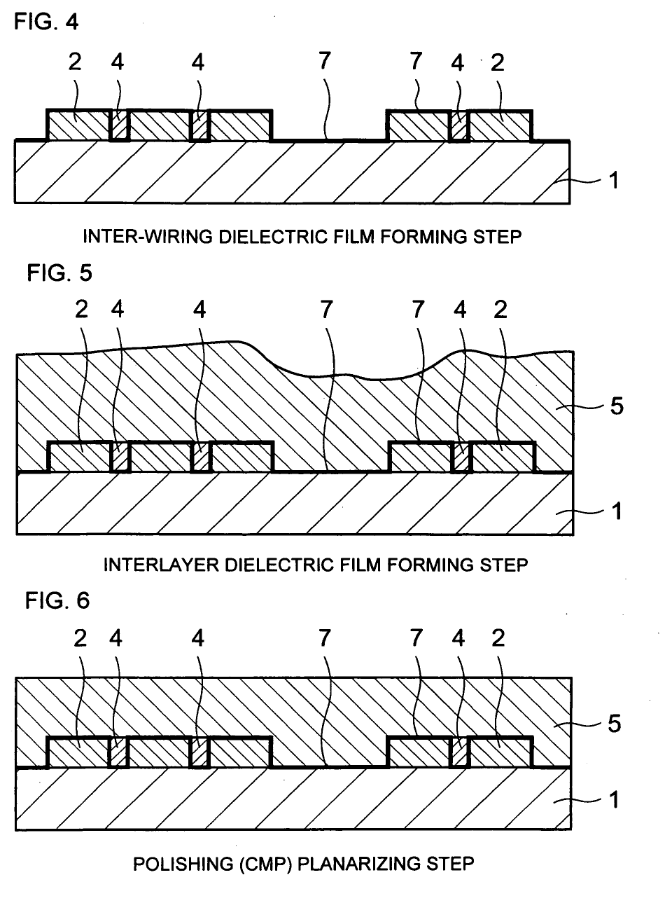

FIG. 4 shows a cross-sectional view of the exemplary semiconductor device for describing the step of forming inter-wiring dielectric films. Inter-wiring dielectric films 4 are formed through coating liquid material and drying and hardening the same. As the liquid material, for example, materials of SOG (spin on glass) may be used. In the present embodiment, the inter-wiring dielectric films 4 can be formed to the upper surface of the wirings 2 by repeating the steps of coating and drying and hardening several times.

FIG. 9 shows a cross-sectional view for describing the coating by a slit coat method in accordance with an exemplary embodiment. In the embodiment, a wiring side surface of the substrate 1 including the wirings 2 is faced downward, and exuded liquid material 10a, while contacting the same with the wiring side surface of the substrate 1 including the wirings 2, is coated by scanning a coating head 9. Liquid material 10 is supplied from a tank 11, and exudes from an end face of a slit 9a that linearly opens in the coating head 9 by the capillary phenomenon of the slit 9a and a pressure caused by the gravity of the liquid material 10 in the tank 11. The pressure can be changed by adjusting the height of the tank 11.

Where the pitch between the wirings 2 is narrower than the width of the slit 9a, the liquid material 10 enters between the wirings 2, and where the pitch between the wirings 2 is wider, the liquid material 10 is repelled by the water repelling film 7 that is present on the surface, and does not stick to the surface. The width of the slit 9a can be appropriately selected such that the liquid material 10 is selectively filled between the wirings 2 having a pitch narrower than the width of the slit.

Also, the thickness of the inter-wiring dielectric films 4 is appropriately adjusted by repeating the coating and drying/hardening steps, such that the inter-wiring dielectric films 4 are filled to a predetermined height below the upper surfaces of the wirings 2. The inter-wiring dielectric films 4 may preferably be formed to a predetermined thickness or greater such that, when an interlayer dielectric film 5 is subsequently formed on the upper surfaces by a plasma CVD process, and even when spaces to be embedded between the wirings 2 remain, voids (gaps) are not created when the spaces are embedded by the plasma CVD.

FIG. 5 shows a cross-sectional view of the exemplary semiconductor device after the step of coating an interlayer dielectric film. The interlayer dielectric film 5 is formed by a plasma CVD process, using a silicon compound (for example, TEOS (tetraethoxysilane)) as a raw material. The film thickness thereof, even at its thinnest portions, is to be formed greater than the thickness of the wirings.

FIG. 6 shows a cross-sectional view of the exemplary semiconductor device after the step of planarizing by chemical mechanical polishing (CMP). The entire upper surface of the interlayer dielectric film 5 is polished and planarized by using chemical mechanical polishing (CMP).

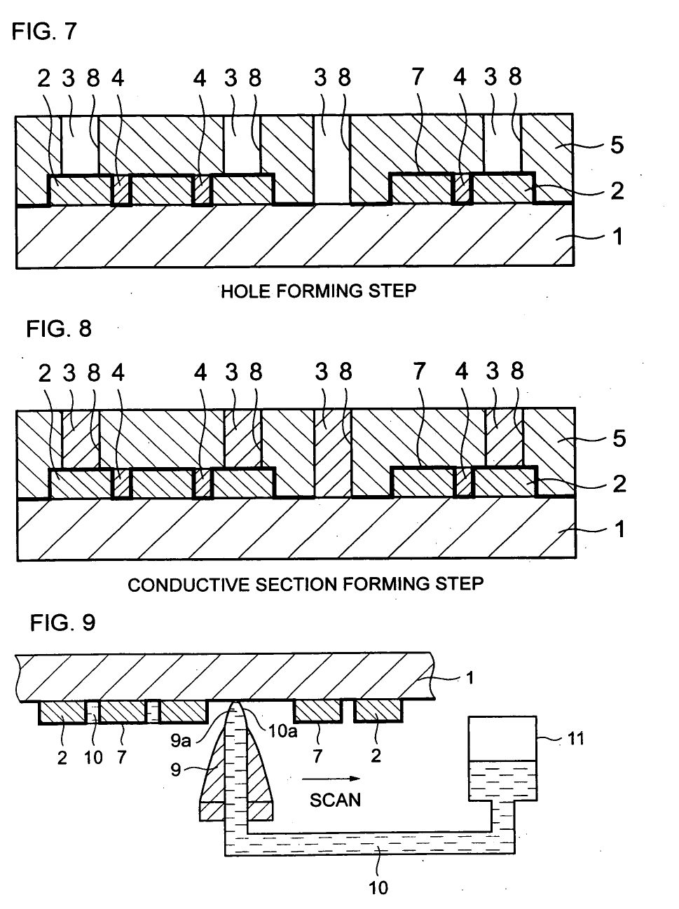

FIG. 7 shows a cross-sectional view of the exemplary semiconductor device after the step of forming holes. Holes 8 can be formed by plasma etching or laser processing.

FIG. 8 shows a cross-sectional view after conductive sections are formed in the holes. Conductive sections 3 can be formed by, for example, a method in which well known Al sputtering is conducted and then heating reflow is conducted, a method using CVD of tungsten, or a method using Cu Damashin. Also, polysilicon doped with impurities can be used as the conduction sections 3.

According to the first exemplary embodiment described above, the following effects can be obtained. The liquid material 10 can be repelled on the upper surfaces of the wirings 2 and the surfaces of the substrate 1, such that the inter-wiring dielectric films 4 are prevented from being formed on the upper surfaces of the wirings 2 and the surfaces of the substrate 1, and only fine gaps between the wirings 2 are filled, such that the amount of the liquid material 10 used can be few. Also, since SOG film material is used as the liquid material 10 with viscosity and flowability that are suitable for the filling of minute gaps between the wirings 2, the capillary phenomenon caused by the fine gaps between the wirings 2 can be effectively used.

Furthermore, because SOG films are not exposed on the inner walls of the holes 8, changes and constrictions of the shape of the holes, or peeling of the conductive sections 3 do not occur by the phenomenon of absorption and discharge of gas and moisture. Accordingly, the reliability of the wirings would increase, as a result of the electrical connection between lower wirings and upper wirings through the conductions sections 3 becoming difficult.

Furthermore, the multilayer wirings can be planarized in a broad range, and can be accurately formed even when upper layer wirings are miniaturized.

Moreover, the step of forming the inter-wiring dielectric films 4 in fine gaps between the wirings 2 is simple and easy, and a semiconductor device that can be manufactured with the quality thereof unaffected can be obtained, while suppressing the use of the material, electrical power and PFC.

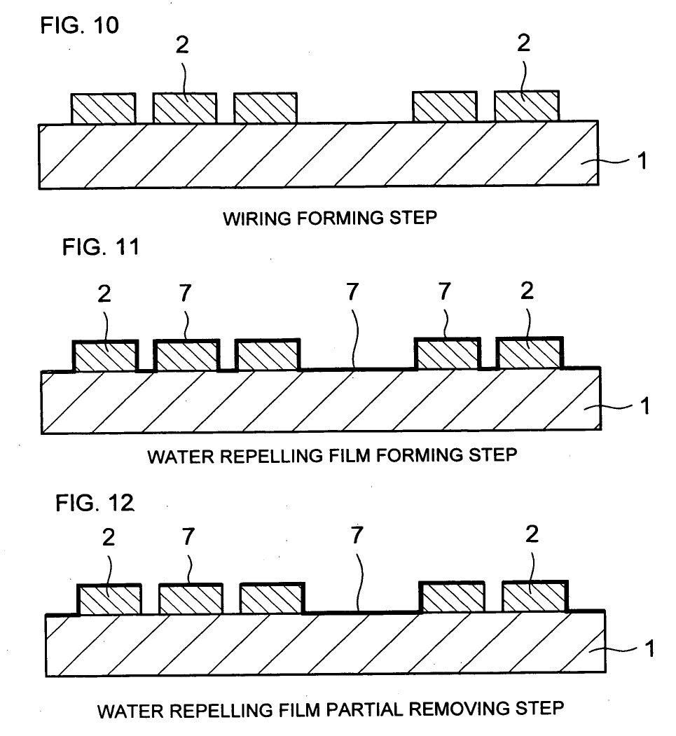

A second exemplary embodiment is described below around the process of removing a water repelling film. FIG. 10 and FIG. 11 show cross-sectional views for describing the step of forming wirings and the step of forming water repelling films, which are conducted by a method similar to the first embodiment.

FIG. 12 shows a cross-sectional view of a semiconductor device after the water repelling films are partially removed. The removal of the water repelling films 7 can be conducted in areas where inter-wiring dielectric films 4 are to be formed. The removal of the water repelling films 7 in areas where inter-wiring dielectric films 4 are to be formed can be conducted by a slit coat method indicated in FIG. 9. In other words, liquid for removing the water repelling films 7 (for example, alkali or acid) may be coated by the slit coat method indicated in FIG. 9, such that the liquid for removing the water repelling films 7 is filled in fine gaps between the wirings 2.

If the liquid does not rapidly remove the water repelling films 7, the water repelling films 7 are not eroded while it is being coated, and by leaving it for a while after coating, only the water repelling films 7 in fine gaps between the wirings 2 can be removed by the remover liquid remaining only in the fine gaps between the wirings 2. The remover liquid is removed by washing.

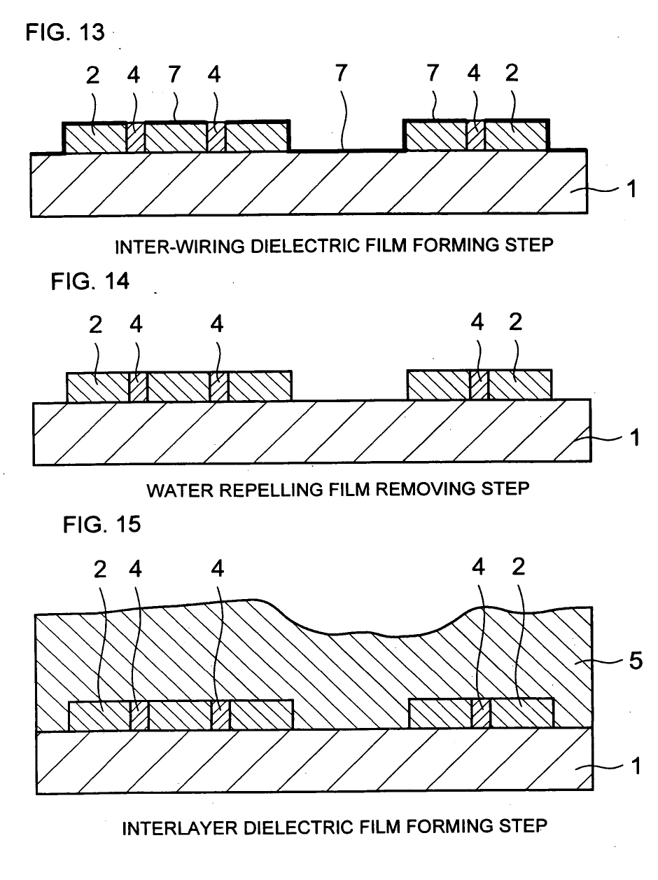

FIG. 13 shows a cross-sectional view of the semiconductor device after inter-wiring dielectric films are formed. The inter-wiring dielectric films 4 are provided in a similar manner as the first exemplary embodiment.

FIG. 14 shows a cross-sectional view of the semiconductor device after all the remaining portions of the water repelling films are removed. Here, only a part thereof can be removed. The removal can be conducted by irradiating ultraviolet light (with a wavelength of 172 nm) to the water repelling films 7. Bonds of the fluororesin plasma polymerized films are cut by the ultraviolet light, and they are removed. Also, when the decomposition is promoted by heat, like the fluororesin plasma polymerized films, they are heated to promote the decomposition. In the present exemplary embodiment, it is done by heating the substrate at 120° C. Heating is effective even when it is conducted after irradiation of ultraviolet light.

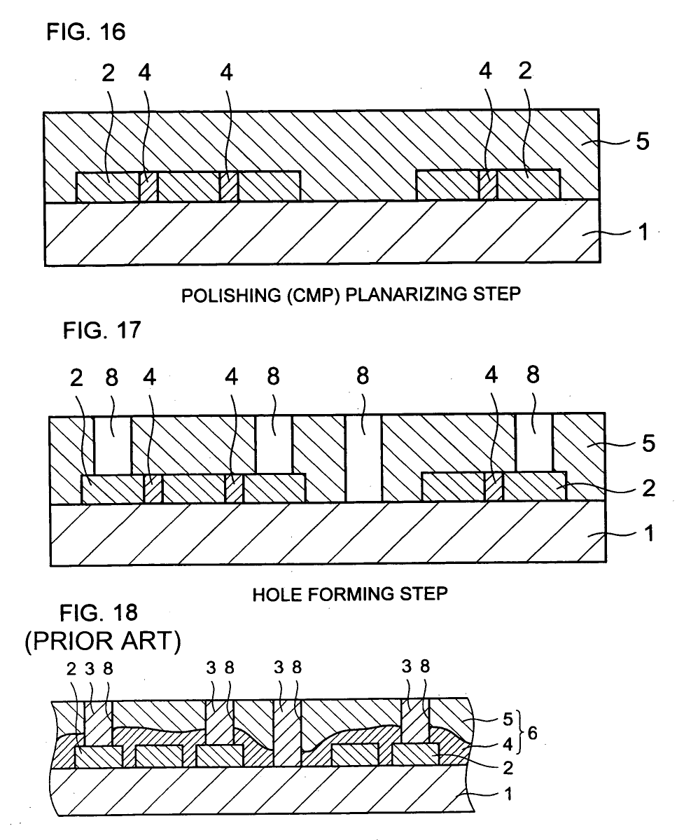

The steps shown in FIG. 15-FIG. 17 are conducted in a similar manner as the first exemplary embodiment.

According to the second exemplary embodiment, the following effects can be obtained.

By removing the water repelling films 7, in areas other than areas that require the water repelling films 7 such as the upper surfaces of the wirings 2 and the surfaces of the substrate, the semiconductor device can prevent influences by contaminations from the water repelling films 7 or changes of electrical characteristics.

It should be understood that the invention is not limited to the exemplary embodiments described above, and also include modified examples described below.

The step of forming the water repelling films 7 used in the invention, in the case of a wet-type method, may employ dip treatment using surfactant such as anion or cation, treatment using reactive silane compound, silane alminate or titanate coupling agent, or SAM film formation. When treatment using reactive silicon compound, such as, for example, chlorosilane, alkoxysilane, aminosilane, or silazane is conducted, there is a possibility that a monomolecular layer is formed, but the layer can be treated as a film and is included in the present application. Other monomolecular layers having water repelling property can be treated as films, and are to be included in the present application.

Also, in the case of a dry-type method, fluoride treatment using plasma, an electron gun, or photoexcitation method, plasma polymerization of silicone film, oxidization treatment using ozone gas generated by plasma, an electron gun or photoexcitation method, or vapor deposition of silane coupling agent may be used.

The liquid material for forming the inter-wiring dielectric films 4 used in the present invention is not limited to materials for SOC films, and other coating liquid for forming SiO2 coats or Low-k materials (low dielectric constant dielectric film materials) can be used.

The step of removing parts of the water repelling films 7 used in the present invention can be performed solely by heating as a dry-type method, besides the method that uses ultraviolet light irradiation and heating combined. Also, another removal method using gas that is activated by an electron gun, photoexcitation, or plasma can be used.

The pitch between the wirings 2 where the inter-wiring dielectric films 4 are formed in the present invention is acceptable if it is narrower than a pitch between the wirings 2 where the holes 8 are not formed. More specifically, it is acceptable if it is less than a pitch between the wirings 2 which makes it difficult to form a uniform film by a plasma CVD process. The gap between the wirings 2 where the inter-wiring dielectric films 4 are to be formed can be decided by selecting the width of the slit 9a in the slit coat method indicated in FIG. 9.

The liquid repelling film used in the present invention does not have to be the water repelling film 3. For example, when liquid materials including organic solvent are used, a film that repels these liquid materials is used.

Technical ideas that may be derived from each of the exemplary embodiments and the modified examples described above are described as follows.

In a semiconductor device recited in claim 9, the semiconductor device is characterized in that the pitch between wirings where inter-wiring dielectric films are formed is 0.5 μm or less.

If the pitch between wirings where inter-wiring dielectric films are formed is 0.5 μm or less, films can be formed in other inter-wiring gaps by plasma CVD.

In a semiconductor device recited in claim 10, the semiconductor device is characterized in that the films formed through coating liquid material are SOG films.

It can be suitable to use a SOG film in view of its coating performance to inter-wiring fine gaps, and the results of its use in semiconductor devices.

Accordingly, while this invention has been described in conjunction with the specific embodiments thereof, it is evident that many alternatives, modifications, and variations will be apparent to those skilled in the art. Accordingly, preferred embodiments of the invention as set forth herein are intended to be illustrative, not limiting. There are changes that may be made without departing from the spirit and scope of the invention.

1. A dielectric film forming method for a semiconductor device for forming a dielectric film including an inter-wiring dielectric film and an interlayer dielectric film that planarizes irregularities caused by wirings formed on a substrate, the method comprising:
forming wirings on a substrate;
forming a liquid repelling film on surfaces of the wirings and surfaces of the substrate;
forming an inter-wiring dielectric film by coating liquid material on surfaces where the liquid repelling film is formed;
forming an interlayer dielectric film on the wirings and the inter-wiring dielectric film; and
polishing and planarizing an upper surface of the interlayer dielectric film.

2. The dielectric film forming method according to claim 1, the liquid material being coated by a slit coat method in which, while contacting liquid material exuded from an end face of a slit with a surface of the substrate where the wirings are provided, the slit is scanned.

3. The dielectric film forming method for a semiconductor device according to claim 2, further comprising:
removing a part of the liquid repelling film between the step of forming the liquid repelling film and the step of forming the inter-wiring dielectric film.

4. The dielectric film forming method according to claim 2, further comprising:
removing all or a part of exposed portions of the liquid repelling film between the step of forming the inter-wiring dielectric film and the step of interlayer dielectric film.

5. The dielectric film forming method according to claim 2, the inter-wiring dielectric film being an SOG film.

6. The dielectric film forming method according to claim 5, the step of forming the interlayer dielectric film including a plasma CVD step.

7. The dielectric film forming method according to claim 6, the step of polishing and planarizing the upper surface of the interlayer dielectric film being CMP.

8. A semiconductor device having a dielectric film including an inter-wiring dielectric film and an interlayer dielectric film that planarizes irregularities caused by wirings formed on a substrate, the semiconductor device comprising:
an inter-wiring dielectric film formed by filling between the wirings to a predetermined height below an upper surface of the wirings;
a dielectric film including an interlayer dielectric film formed on the wirings and the inter-wiring dielectric film; and
a liquid repelling film formed on at least one of a boundary between the wirings and the inter-wiring dielectric film and a boundary between the substrate and the interlayer dielectric film.

9. The semiconductor device according to claim 8, the inter-wiring dielectric film being formed between the wirings with a pitch narrower than a pitch of wirings where holes are formed.

10. The semiconductor device according to claim 9, the inter-wiring dielectric film being formed by coating a liquid material.

11. The semiconductor device according to claim 10, the interlayer dielectric film being a plasma CVD film.

12. The semiconductor device having a dielectric film including an inter-wiring dielectric film and an interlayer dielectric film that planarizes irregularities caused by wirings formed on a substrate, the semiconductor device, comprising:
a dielectric film formed by the dielectric film forming method according to claim 1.
